(19) United States
(12) Patent Application Publication
(10) Pub. No.: US 2025/0332615 A1
(43) Pub. Date: Oct. 30, 2025

(54) PROCESSING MODULE HAVING A PRIMING SYSTEM

(71) Applicant: Applied Materials, Inc., Santa Clara, CA (US)

(72) Inventors: Manikandan JAYARAMAN, Santa Clara, CA (US); Jagadeesh Kumar SUKUMARAN, Santa Clara, CA (US); Jagan RANGARAJAN, San Jose, CA (US); Yuwen HUANG, Santa Clara, CA (US); Yue ZHENG, Santa Clara, CA (US); Yunshuang DING, Santa Clara, CA (US); Ekaterina MIKHAYLICHENKO, Santa Clara, CA (US); Timothy THAO, Santa Clara, CA (US)

(21) Appl. No.: 18/647,587

(22) Filed: Apr. 26, 2024

(51) Int. Cl. B08B 3/02; B01D 19/00; B08B 3/08; B08B 5/02; B24B 37/34; H01L 21/67

(52) U.S. Cl. CPC B08B 3/02; B01D 19/0031; B08B 3/08; B08B 5/02; B24B 37/34; H01L 21/67051; B08B 2203/0247

(57) ABSTRACT

Disclosed herein are a priming system, a substrate cleaning module having the priming system, and a method of operating the substrate cleaning module. The priming system includes a diversion valve configured to selectively direct a flow of an agent; a priming nozzle mechanism coupled with the diversion valve; and a separation chamber coupled with the priming nozzle mechanism. The priming nozzle mechanism includes a releasing nozzle configured to release the agent inside the separation chamber, and the separation chamber is configured to process the agent. The method of operating the substrate cleaning module includes operations to redirect an agent from a dispensing nozzle to a releasing nozzle during a time period when the dispensing nozzle stops dispensing the agent. The method further includes operations to continue dispensing the agent by the releasing nozzle during the same time period when the dispensing nozzle stops dispensing the agent.

### BACKGROUND

### Field

Embodiments of the present disclosure generally relate to a substrate processing module, and, more particularly, to a cleaning module having a priming system.

### Description of the Related Art

A substrate used in semiconducting processing is typically subject to chemical mechanical polishing (CMP) to planarize or polish the surface of a material deposited on the substrate. After CMP is completed, a polished substrate may be further cleaned and/or dried. In a cleaning unit for cleaning a substrate, cleaning agents, such as deionized water, nitrogen, or other chemicals, are dispensed on the substrate via a delivery system. The cleaning agents in delivery lines may be pressurized to reach certain dispensing thresholds, such as pressure or flow rate, before being dispensed via a nozzle. It may take several seconds or an even longer time period for the delivery system to get ready to dispense the cleaning agents. The time period for the cleaning agents to reach a pre-determined dispensing threshold is known as a ramp-up time. This ramp-up time is added to processing cycles whenever the cleaning unit pauses and then restarts dispensing the cleaning agents. The overall throughput of the cleaning unit can be impacted by the ramp-up time.

Accordingly, there is a need for an improved processing module that can reduce the ramp-up time to increase the throughput of the processing module.

### SUMMARY

In one example embodiment, a priming system for a substrate cleaning module includes a first diversion valve configured to selectively direct a first flow of a first agent; a priming nozzle mechanism coupled with the first diversion valve; and a separation chamber coupled with the priming nozzle mechanism. The priming nozzle mechanism includes a releasing nozzle and configured to release the first agent inside the separation chamber, the separation chamber configured to process the first agent. The priming system may further include a second diversion valve configured to selectively direct a second flow of a second agent. The priming nozzle mechanism is coupled with the second diversion valve and configured to release the second agent in the separation chamber, the separation chamber configured to process the second agent.

In another example, a cleaning module for cleaning a substrate includes a dispensing nozzle mechanism including a dispensing nozzle configured to dispense a first agent toward a substrate disposed inside a processing volume of the cleaning module; a priming system disposed outside the processing volume and configured to dispense the first agent during a time period when the dispensing nozzle stops dispensing the first agent; and a first diversion valve coupled with both the dispensing nozzle mechanism and the priming system and configured to selectively direct a first flow of the first agent. The priming system includes a releasing nozzle coupled with the first diversion valve and a separation chamber configured to process the first agent, the releasing nozzle configured to release the first agent inside the separation chamber. The priming system may further include a second diversion valve configured to selectively direct a second flow of a second agent, and the priming nozzle mechanism is coupled with the second diversion valve and configured to release the second agent inside the separation chamber.

In yet another example, a method for operating a substrate cleaning module, includes directing a first agent from an agent supply source to a dispensing nozzle of the cleaning module; causing the dispensing nozzle to dispense the first agent inside a processing volume of the cleaning module; stopping the first dispensing nozzle from dispensing the first agent during a time period; redirecting the first agent from the dispensing nozzle to a priming system disposed outside the processing volume during the time period; causing a releasing nozzle of the priming system to continue dispensing the first agent during the time period; and redirecting the first agent from the priming system to the dispensing nozzle at an end of the time period. The method may further include stopping the dispensing nozzle of the cleaning module from dispensing a second agent inside the processing volume during the time period; redirecting the second agent from the dispensing nozzle to the priming system during the time period; causing the releasing nozzle of the priming system to continue releasing the second agent during the time period; and redirecting the second agent from the priming system to the dispensing nozzle at the end of the time period.

In another example, a cleaning module for cleaning a substrate includes a dispensing nozzle mechanism that can dispense two cleaning agents through a single nozzle inside the processing volume. The interaction between the two cleaning agents inside the nozzle can determine the flow resistance experienced by each cleaning agent. This flow resistance can affect the requirement of the fluid pressure and the ramp-up control. A priming system disposed outside the processing volume will have a releasing nozzle that can release the two agents in a manner that it creates the same or almost same flow resistance as those created by the dispensing nozzle inside the processing volume. Diversion valves are used to switch the flow of a cleaning agent between the point of use inside the processing area and the outside releasing point. The priming system can have several flowing priming nozzles to support multiple dispensing nozzles or cleaning modules. The priming system can maintain a cleaning agent at desired threshold levels outside the module and immediately start dispensing the cleaning agent at point of use inside the processing area when required. When a process involves intermittent dispensing of a cleaning agent, the priming system can substantially increase the throughput of the process.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top view of an exemplary chemical mechanical polishing (CMP) processing system, according to one or more embodiments.

FIG. 2 is a schematic cross-sectional view of an example of an integrated cleaning and drying (ICD) module in the CMP processing system having a priming system, according to one or more embodiments.

FIG. 3 is a schematic top perspective view of the ICD module having a priming system, according to one or more embodiments.

FIG. 4A is a schematic diagram illustrating a delivery system having a priming system, according to one or more embodiments.

FIG. 4B shows a schematic configuration of a three-way diversion valve formed by a combination of two one-way valves, according to an embodiment.

FIG. 4C shows a schematic priming nozzle mechanism, according to an embodiment of the present disclosure.

FIG. 5A is another schematic diagram illustrating a delivery system having a priming system, according to one or more embodiments.

FIG. 5B is another schematic diagram illustrating a delivery system having a two-phase cleaning agent, according to one or more embodiments.

FIG. 6A is a schematic diagram of a separation chamber of a priming system having a releasing valve, according to one or more embodiments.

FIG. 6B is a schematic configuration showing a priming system coupled with two ICD modules, according to one or more embodiments.

FIG. 6C is a schematic separation chamber supporting two cleaning modules, according to one or more embodiments.

FIG. 6D is a schematic bottom perspective view of a manifold of the priming system, according to one or more embodiments.

FIG. 7 is a method for operating an ICD module, according to one or more embodiments.

To facilitate understanding, identical reference numerals have been used, where possible, to designate identical elements that are common to the figures. It is contemplated that elements disclosed in one embodiment may be beneficially utilized in other embodiments without specific recitation thereof with respect thereto.

### DETAILED DESCRIPTION

Embodiments described herein generally relate to an apparatus and method for processing a substrate, and more particularly, to a cleaning module which may be used to clean and/or dry the surface of a substrate in a semiconductor device manufacturing process. The cleaning module may be an integrated cleaning and drying module. The integrated cleaning and drying module include a processing volume that contains a substrate to be cleaned by cleaning agents. The integrated cleaning and drying module further include a priming system disposed outside the processing volume and configured to keep cleaning agents dispensed at predetermined threshold levels, such as pressure or flow rates. During a period when a dispensing nozzle of the cleaning module pauses dispensing the cleaning agents inside the processing volume, the cleaning agents can be diverted to a releasing nozzle of the priming system which is configured to dispense cleaning agents similarly as the dispensing nozzle inside the ICD module. With this priming system, the cleaning agent can be immediately redirected to the dispensing nozzle when the cleaning agent is needed inside the processing volume. The need for a dispensing nozzle to have a ramp-up time is reduced.

For example, the dispensing nozzle is coupled with a releasing nozzle via a diversion valve. The diversion valve is coupled to a source of the cleaning agents and is configured to direct the cleaning agents to either the dispensing valve or the releasing valve. When the dispensing nozzles inside the processing chamber dispense the cleaning agents, the diversion valves direct the cleaning agents to the dispensing nozzles. When the dispensing nozzles inside the processing chamber pause dispensing the cleaning agents, the diversion valves direct the cleaning agents to the releasing nozzles of the priming system. When the dispensing nozzles restart dispensing the cleaning agents, the diversion valves redirect the cleaning agents from the releasing nozzles to the dispensing nozzles.

The priming system also includes a separation chamber configured to process the cleaning agents released by the priming system. For example, when the cleaning agents include constituents in a gaseous phase and a liquid phase, the separation chamber can separate those constituents. The separated constituents can be easily recycled or disposed.

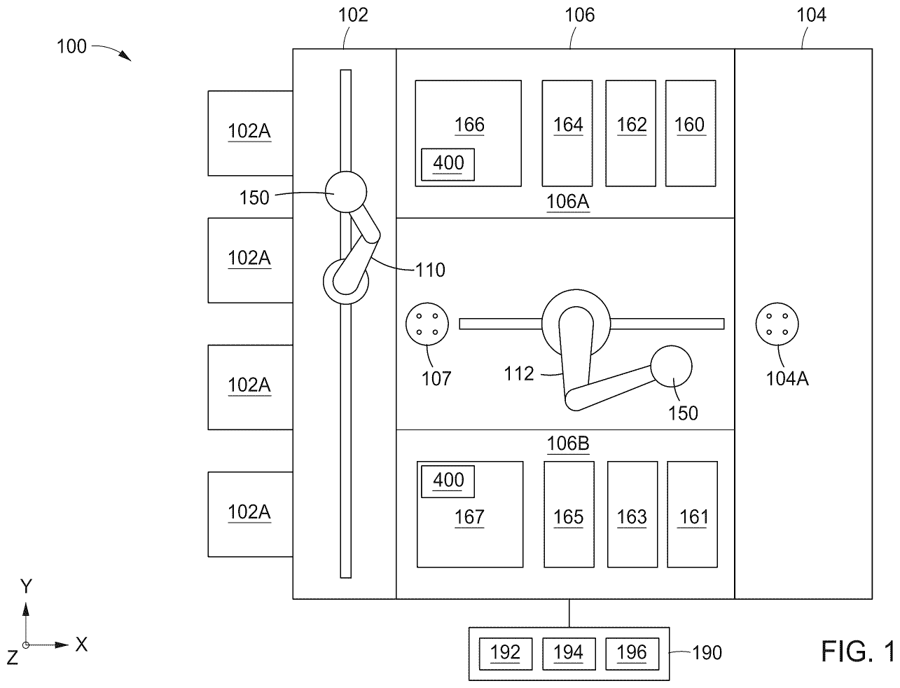

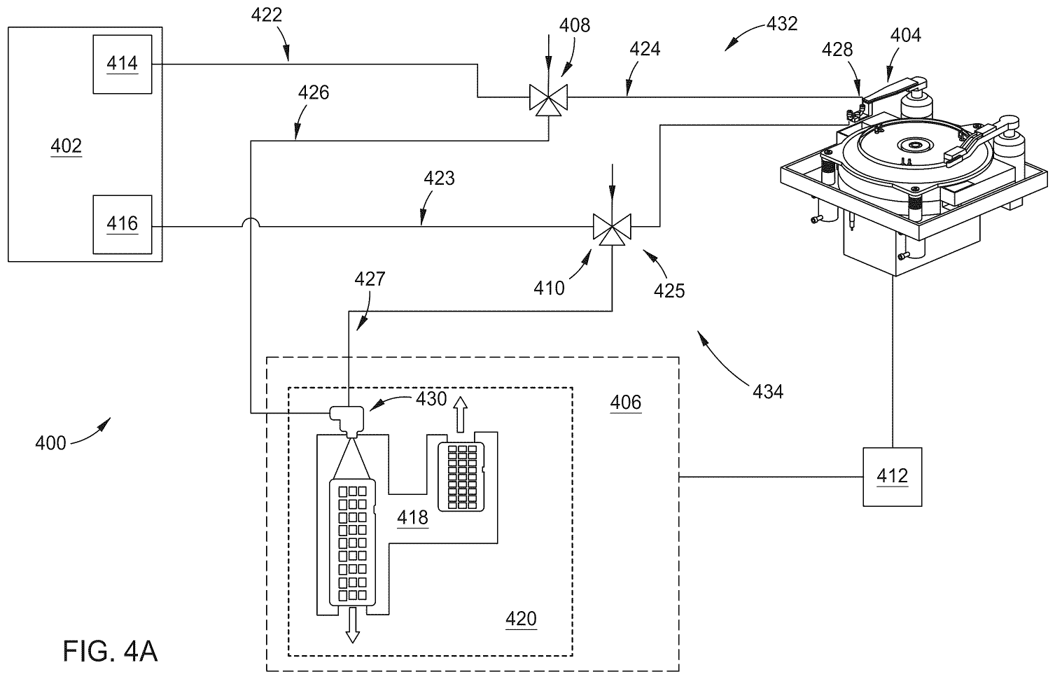

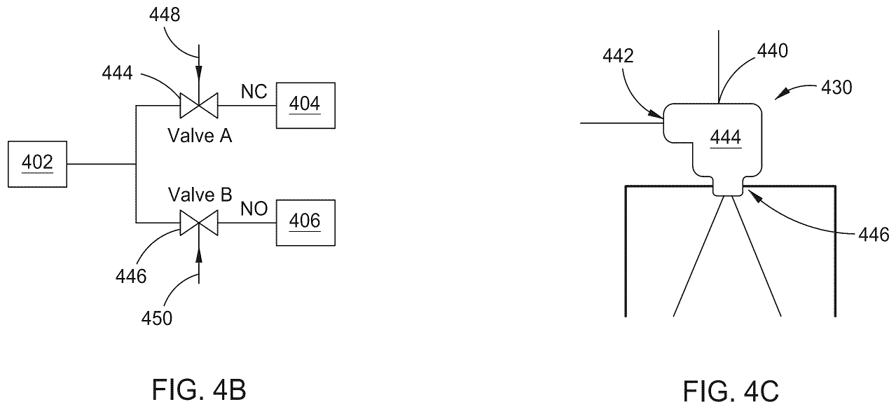

FIG. 1 is a schematic plan view illustrating one embodiment of a chemical mechanical polishing (CMP) system 100 utilizing an agent supply system 400 (details shown in FIG. 4) as described herein. The CMP system 100 includes a factory interface 102, a polishing unit 104, and a cleaning unit 106. An agent supply system 400 may be installed in the polish unit 104 and or the cleaning unit 106. The factory interface 102 may include one or more loading stations 102A. The loading stations 102A may be, for example, FOUPs or cassettes. Each loading station 102A may include one or more substrates 150 for CMP processing in the CMP processing system 100. A first substrate handler 110 is provided to transfer substrates 150 between the loading stations 102A and the cleaning unit 106. The first substrate handler 110 may also transfer substrates 150 from the cleaning unit 106 to the loading stations 102A. A second substrate handler 112 is also provided to transfer substrates 150 between the cleaning unit 106 and the polishing unit 104. For example, the first substrate handler 110 transfers a substrate 150 from a loading station 102A to the cleaning system 106, e.g., to a cleaner pass-through 107, where the substrate 150 can be picked up by the second substrate handler 112.

As shown in FIG. 1, the cleaning unit 106 may be comprised of two cleaning units 106A, 106B disposed in parallel to one another on opposite sides of the second substrate handler 112. The cleaning unit 106A may include a plurality of modules, such as a first cleaning module 160, a second cleaning module 162, a third cleaning module 164, and a fourth cleaning module 166. The cleaning unit 106B may include a plurality of modules, such as a first module 161, a second module 163, a third module 165, and a fourth module 167. In an embodiment, any one of the modules 160-167 may include an agent supply system 400 as set forth in the present disclosure, according to an embodiment. In an embodiment, two or more modules 160-167 may share a single agent supply system 400.

The first cleaning module 160 may be, for example, a pre-clean module that performs a pre-clean process, such as a buffing process, on the substrate 150 before the substrate 150 is transferred therefrom using the second substrate handler 112. The second cleaning module 162 and the third cleaning module 164 may be, for example, any one or combination of contact and non-contact cleaning systems for removing polishing byproducts from the surfaces of the substrate 150 before the substrate 150 is transferred therefrom using the second substrate handler 112, such as in cleaning systems commonly referred to as spray boxes and/or scrubber brush boxes. The fourth cleaning module 166 may be, for example, a drying unit or a final cleaning and drying unit.

According to an embodiment, cleaning unit 106B may be essentially a mirror-duplicate of the cleaning unit 106A. In such a case, the first module 161 is similar to the first cleaning module 160, the second module 163 is similar to the second cleaning module 162, the third module 165 is similar to the third cleaning module 166, and the fourth module 167 is similar to the fourth cleaning module 166. Accordingly, the description herein and the depiction of cleaning unit 106A in the Figures is to be understood inferentially as also a description and depiction of cleaning unit 106B.

Alternatively, one or more of the first module 161, second module 163, third module 165, and fourth module 167 may be a module configured to perform a process other than a cleaning process. For example, one or more of the first module 161, second module 163, third module 165, and fourth module 167 may be a metrology station for measuring the thickness of a material layer disposed on the substrate 150 before and/or after polishing, to inspect the substrate 150 after polishing to determine if a material layer has been cleared from the field surface thereof, and/or to inspect the substrate surface for defects before and/or after polishing. As another example, one or more of the first module 161, second module 163, third module 165, and fourth module 167 may be a location specific (LSP) polishing module configured to polish only a portion of a substrate surface after the substrate 150 has been polished with a polishing module to touch up, e.g., remove additional material from, a relatively small portion of the substrate 150, for example, based on the measurement or surface inspection results obtained using a metrology station.

The cleaner pass-through 107 is disposed between the cleaning units 106A and 106b, where the second substrate handler 112 is also positioned. The second substrate handler 112 may pick up the substrate 150 from the cleaner pass-through 107 and then transfer the substrate 150 to a transfer station 104A within the polishing unit 104. Following CMP processing on the substrate in the polishing unit 104, the second substrate handler 112 may retrieve the substrate 150 from the transfer station 104A within the polishing unit 104 and then transfer the substrate 150 to various modules in the cleaning unit 106.

A controller 190, such as a programmable computer, is connected to elements of cleaning unit 106 and is configured to operate the elements of the cleaning module 106. For example, the controller 190 may control the loading, unloading and cleaning of substrates 150 by the cleaning unit 106.

The controller 190 can include a central processing unit (CPU) 192, a memory 194, and support circuits 196, e.g., input/output circuitry, power supplies, clock circuits, cache, and the like. The memory 194 and support circuits 196 are connected to the CPU 192. The memory 194 may be is a non-transitory computable readable medium, and can be one or more readily available memory such as random access memory (RAM), read only memory (ROM), floppy disk, hard disk, or other form of digital storage. In addition, although illustrated as a single computer, the controller 190 could be a distributed system, e.g., including multiple independently operating processors and memories. This architecture is adaptable to various cleaning situations based on programming of the controller 190 to control the order and timing that the substrates 150 are moved between the various modules of the cleaning unit 106, and to control individual operations of each of the various modules of the cleaning unit 106.

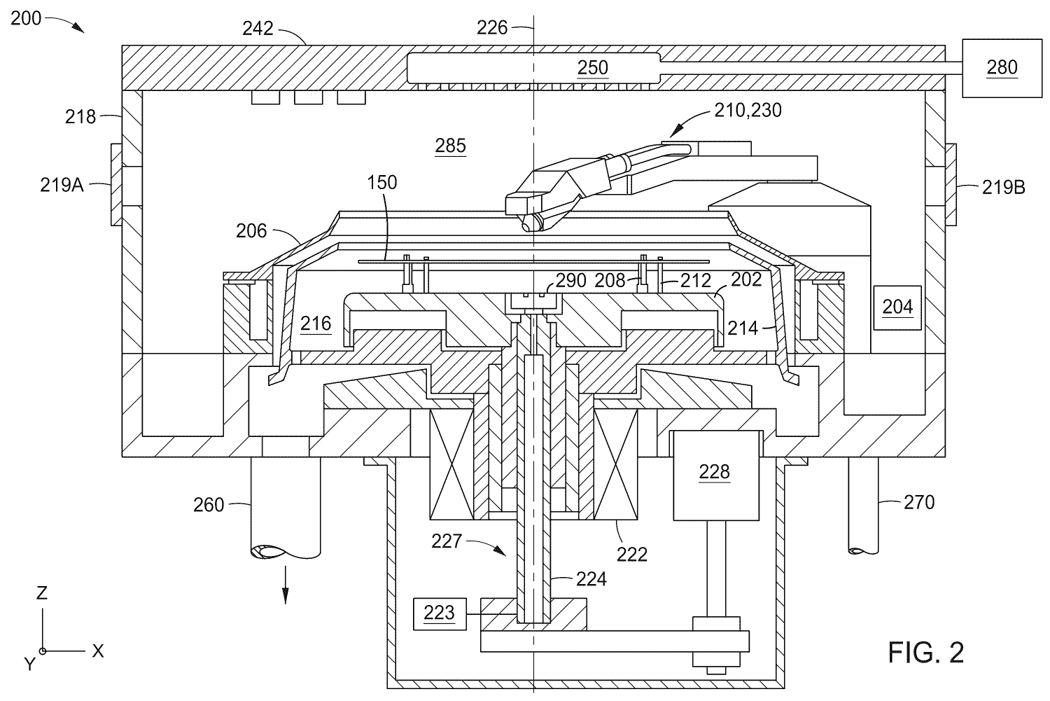

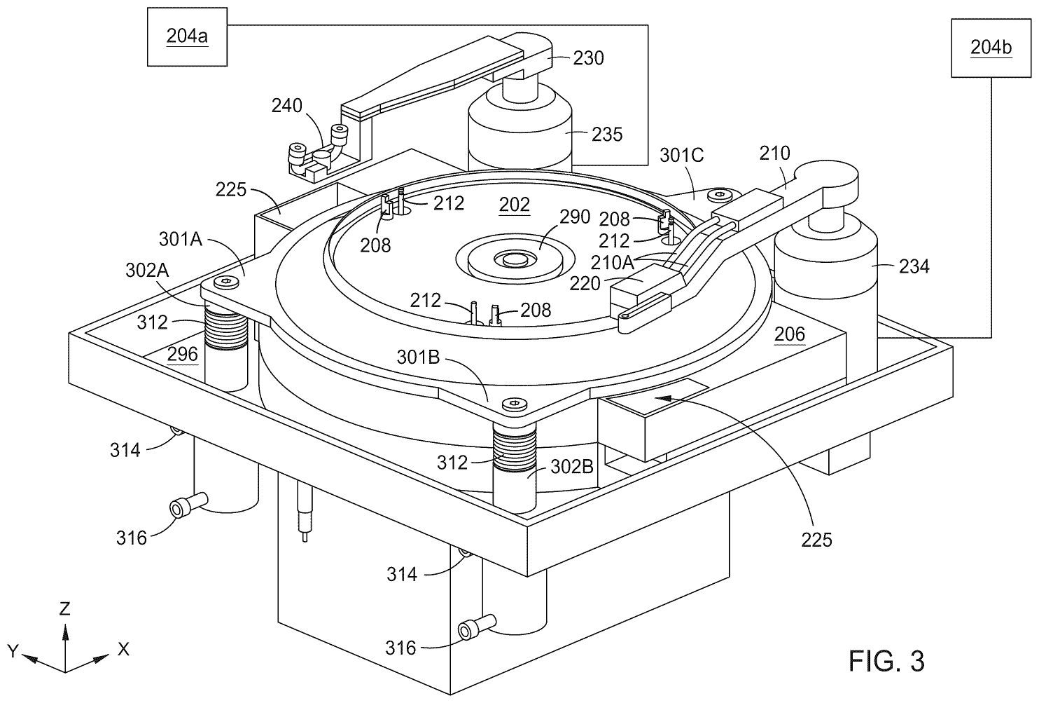

FIG. 2 is a schematic cross-sectional view of an integrated cleaning and drying (ICD) module 200 having a priming system 204, according to one or more embodiments. FIG. 3 is a schematic top perspective view of the ICD module of FIG. 2, according to one or more embodiments. The ICD module 200 may receive a substrate, e.g., the substrate 150, for a final clean and dry process after the substrate 150 has been cleaned within one or more of the modules of the cleaning unit 106. The ICD module 200 may be utilized to remove contamination from the substrate 150. The ICD module 200 may also remove residual moisture from the substrate 150. In an example, the fourth cleaning module 166 of FIG. 1 may be implemented as the ICD module 200 described herein.

The ICD module 200 includes an enclosure 218 enclosing a plenum 285. Inside the plenum 285, the ICD module 200 further includes a process rotor 202, a collection rotor 214, a rotor cover 206, and one or more sweep arms 210, 230. In one or more embodiments, the ICD module 200 includes an agent supply system 400 disposed inside the plenum 285 and coupled with the one or more sweep arms 210, 230. In another embodiment, the agent supply system 400 may be disposed outside the plenum 285. The priming system 204 is configured to maintain cleaning agents at predetermined thresholds, such as pressure or flow rate, such that the ramp up time to dispense the cleaning agents is substantially reduced. The agent supply system 400 will be further described later in the specification in reference to FIGS. 4-7. The ICD module may further include a primary exhaust 260, a secondary exhaust 270, and air intake 280.

The enclosure 218 includes doors 219A, 219B, which may selectively open to provide access to the plenum 285 for inserting or removing the substrate 150 from the ICD module 200. Any fumes or liquids used and/or generated during the cleaning process in the ICD module 200 are removed via the primary exhaust 260 and/or the secondary exhaust 270. Positive air flow through the plenum 285 may be provided by a fan/filter unit (FFU) 242. The FFU 242 may be connected to the enclosure 218, for example. The FFU 242 includes the air intake 280 and a plenum 250. Air flows from the air intake 280, through the plenum 250, into the plenum 285 and processing volume 216, and out the primary exhaust 260 and the secondary exhaust 270.

The process rotor 202 includes a plurality of stand-off pins 208 and a plurality of grip pins 212. The stand-off pins 208 extend from a top surface of the process rotor 202. The stand-off pins 208 are configured to support a substrate 150 that is delivered to the ICD module 200 by the substrate handler 112. The stand-off pins 208 may have a minimal cross-section so as to have minimal contact points with the substrate 150 being supported. The grip pins 212 may grip, or hold, the substrate 150 during the cleaning process. The grip pins 212 may have minimal contact with the substrate 150 along the edge of the substrate 150 such that the grip pins 212 do not collect a significant amount of a fluid at a contacting interface and impede the cleaning process of the substrate 150. The process rotor 202 is movable between a raised position and a lowered position by a lift assembly 227 that includes a second drive motor 228 and shaft 224. In FIG. 2, the process rotor 202 is shown in the lowered position.

The collection rotor 214 encloses the processing rotor 202 and defines the processing volume 216 disposed between the collection rotor 214 and the processing rotor 202. The substrate 150 may be cleaned within the processing volume 216. According to an embodiment, the process rotor 202 and the collection rotor 214 are symmetric and share a common rotational axis 226.

A first drive motor 222 may be coupled with the process rotor 202 via shaft 224. The first drive motor 222 rotates the process rotor 202 and the collection rotor 214 about the rotational axis 226. The controller 190 may control the first drive motor 222 to rotate the process rotor 202 and the collection rotor 214 at various rotational speeds set by process recipes contained in the memory 194 of the controller 190. The process rotor 202 and the collection rotor 214 may be rotationally fixed relative to each other, i.e., configured to rotate together.

The second drive motor 228 may also be coupled with the process rotor 202 via shaft 224. The second drive motor 228 may impart linear motion to the process rotor 202 along the rotational axis 226. The controller 190 may control the second drive motor 228 to move the process rotor 202 in the Z direction between the raised position and lowered position. In addition, the second drive motor 228 may be used to move the process rotor 202 in the Z direction in preparation for, or during, a cleaning, rinsing, and/or drying process to precisely position the substrate 150 at a desired distance from fluid nozzles. The first and second drive motor 222 and 228 may be one of a hydraulic, pneumatic, electro-mechanical, and a magnetic motor. The linear movement of the process rotor 202 may be independent of movement of the collection rotor 214.

The sweeping arms 210 and 230 include nozzle mechanisms 220, 240, (FIG. 3) which are configured to dispense cleaning agents to an upper surface of the substrate 150. The nozzle mechanisms 220, 240 may include a droplet nozzle, a megasonic nozzle, fluid jet nozzle, mist nozzle, high pressure nozzle, a kinetic energy nozzle, or any other suitable nozzle. The ICD module 200 of FIG. 2 shows a megasonic nozzle. The ICD module 200 also includes a droplet nozzle, whose view is blocked by the megasonic nozzle and is not shown in FIG. 2. Cleaning and/or rinsing fluids may also be delivered to an underside nozzle mechanism 290 via shaft 224, which is coupled with a fluid source 223. The cleaning agents may include a rinsing agent (e.g., de-ionized water or ozonated water or a mixture of de-ionized water and nitrogen), a cleaning chemical, and a drying agent (e.g., IPA vapor or nitrogen). Depending on the processing operations, the sweeping arms 210 and 230 may need to intermittently dispense the cleaning agents, which requires a pause and then a restart of the release of the cleaning agents. In an embodiment, the sweeping arms 210 and 230 may move back and forth between a center of the substrate 150 and an edge of the substrate 150. Other manners of movements of the sweeping arms are also contemplated by the present application as long as the manner of movement can cover sufficient areas of the substrate 150.

Now referring to FIG. 3, the first sweep arm 210 includes a first drive motor 234 and the second sweep arm 230 includes a second drive motor 235. The first and second drive motors 234 and 235 are configured to move the sweep arms 210 and 230 in an arcuate path that is parallel to a surface of the wafer 150, during the cleaning process, such that the cleaning fluids output by the nozzle mechanisms 220, 240 disposed at one end of the sweep arms are evenly distributed over the surface of the substrate 150. The first and second drive motors 234 and 235 may also be configured to move the sweep arms 210 and 230 axially to set a distance between the nozzles and the surface of the substrate 150.

The first and second sweep arms 210, 230 may each include one or more tubes to deliver cleaning agents to their respective nozzle mechanisms 220, 240. According to an embodiment, each of the first and second sweep arms 210, 230 includes connections 210A for delivering agents and/or electrical signals (e.g., control signals) to the nozzle mechanisms 220, 240. For example, nitrogen, water, and isopropyl alcohol (IPA) may be separately delivered via the connections 210A. Control signals from the controller 190 may also be transmitted to the nozzle mechanisms 220 and 240 via the connections 210A, respectively.

The first and second nozzle mechanisms 220, 240 may each include one or more non-contact cleaning or drying technologies. Each of the first and second nozzle mechanisms 220, 240 may have one, two, three or more nozzles that each may output an agent that may be any combination of liquid or gas. In an embodiment, the first and second nozzle mechanisms 220, 240 may utilize the same cleaning or drying technologies and may couple to a same priming system 204.

In another embodiment, the first nozzle mechanism and the second nozzle mechanism may utilize different cleaning or drying technologies. For example, the first nozzle mechanism 220 may be a megasonic nozzle, and the second nozzle mechanism 240 may be a droplet nozzle. As a result, the first nozzle mechanism 220 is coupled with a first priming system 204b suitable for priming the megasonic nozzle, and the second nozzle mechanism 240 is coupled with a second priming system 204a suitable for priming the droplet nozzle. The megasonic nozzle includes one or more elements, such as a piezoelectric element, configured to alternatively apply compression and rarefraction to the cleaning fluid in an alternating fashion according to a sinusoidal or other pattern to generate a megasonic actuated fluid. The droplet nozzle 240 is configured to atomize the cleaning agents and spay the same toward a substrate for cleaning. In an embodiment, the droplet nozzle 240 receives nitrogen and a cleaning liquid and dispense the two agents via a single nozzle. The nozzle mechanisms 220 and 240 may also include electric circuits (not shown) configured to control the nozzles.

As shown in FIG. 3, the rotor cover 206 also includes two nozzle cups 225 respectively positioned on opposite sides of the top surface of the rotor cover 206. The nozzle cups 225 are each configured and positioned to receive one of the nozzle mechanisms 220, 240. When nozzle mechanisms 220 and 240 are not dispensing cleaning agents, such as, during the substrate loading or unloading, the nozzle mechanisms 220, 240 are positioned in the nozzle cups 225.

The rotor cover 206 further includes flanges 301A, 301B, and 301 coupled with lifters 302A-C that are positioned between a drip pan 296 and respective flanges 301A-C. The lifters 302A-C support the rotor cover 206. The lifters 302A-C are configured to move and position the rotor cover 206 between a lowered position and a raised position. The lifters 302A-C include an actuator, such as an air cylinder, ball-screw assembly, or linear motor that is coupled with the rotor cover 206. According to an embodiment, a portion of each of the lifters 302A-C extends below the drip pan 296. Alternatively, the lifters 302A-C may utilize one or more other lifting mechanisms, such as, for example, hydraulic cylinders or direct drive lifters. The lifters 302A-C include a lifter cylinder 312 having a first pneumatic channel 314 and a second pneumatic channel 316. The first pneumatic channel 314 and second pneumatic channel 316 are connected to a pneumatic controller (not shown), which is controlled by the controller 190 to apply positive and/or negative air pressure to the lifter cylinder 312, thereby raising and lowering the rotor cover 206.

According to an embodiment, the agent supply system 400 (FIG. 2) is coupled with both of the first and second sweep arms 210 and 230. The priming system 204 is configured to keep priming the delivery lines at a similar threshold as used by the nozzle mechanism 220 and 240. Thus, when the dispensing of cleaning agents is needed inside the processing chamber, the primed delivery lines can immediately supply cleaning agents at the predetermined threshold, such as pressure or flow rate.

FIG. 4A illustrates an agent supply system 400 for a cleaning module, according to one or more embodiments. The agent supply system 400 includes an agent supply module 402, a priming system 406, and a dispensing module 404. Diversion valves 408 and 410 are provided in the delivery lines 422-427 to control the flow direction of the cleaning agents. The agent supply system 400 further includes a controller 412 configured to control the operations of the agent supply system 400.

The agent supply module 402 is configured to supply cleaning agents to both the priming system 406 and the dispensing module 404. The agent supply module 402 may supply one or more cleaning agents, such as a first agent 414 and a second agent 416. In an example, the first agent 414 may be an aqueous solution, such as deionized water or a mixture of deionized water with another chemical. The second agent 416 may be a gaseous agent, such as nitrogen. The first agent 414 and the second agent 416 may be mixed by the nozzle mechanism 428 at predetermined pressure levels. The first agent 414 and the second agent 416 may be alternately dispensed by the nozzle mechanism 428. The agent supply module 402 provides the first agent 414 to the priming system 406 and the dispensing module 404 via a first delivery system 432, which includes plumbing line segments 422, 424, 426, and a diversion valve 408. The diversion valve 408 is configure to direct the first agent 414 to either the priming system 406 or the dispensing module 404. In an example, the diversion valve 408 includes a three-way valve that can be electrically controlled. The diversion valve 408 may be a three-way solenoid valve, a three-way pneumatic valve, or any other suitable valves.

It is contemplated that the diversion valve 408 is not limited to a single three-way valve and may include any suitable diversion valves. In an embodiment, the diversion valve 408 may be configured by combining a plurality of one-way valves. In FIG. 4B, two one-way valves, Valve 444 and 446, can form a three-way diversion valve 408. For example, valve 444 functions as a supply valve configured to supply a cleaning agent to the dispensing module 404. Valve 444 couples to the agent supply module 402 on one side and the dispensing module 404 on another side. Valve 444 is operated by a pneumatic line 448 and may be a normally open or normally closed valve. The pneumatic line 448 is capable of switching Valve 444 between an open position and a closed position. Valve 446 functions as a diversion valve configured to divert the cleaning agent to the priming system 406. Valve 446 couples to the agent supply module 402 at one side and the priming system 406 at another side. Valve 446 is operated by another pneumatic line 450 and may be a normally open or normally closed valve. The pneumatic line 450 is capable of switching Valve 446 between an open position and a closed position.

When the dispensing module 404 dispenses a cleaning agent, Valve 444 is switched to an open position, and Valve 446 is switched to a closed position. As a result, the cleaning agent flows from the agent supply module 402 to Valve 444 and then to the dispensing module 404.

When the dispensing module 404 pauses dispensing the cleaning agent, Valve 444 is switched to a closed position, and Valve 446 is switched to an open position. As a result, the cleaning agent flows from the agent supply module 402 to Valve 446 and then to the priming system 406.

Referring back to FIG. 4A, the diversion valve 408 includes an input to receive a flow of the agent 414. The diversion valve 408 includes two outputs: one coupled with the dispensing module 404 via the line segment 424 and the other one coupled with the priming system 406 via the line segment 426.

The agent supply module 402 also provides the second agent 416 to the priming system 406 and the dispensing module 404 via a second delivery system 434, which includes plumbing line segments 423, 425, 427, and a diversion valve 410. The diversion valve 410 is configured to direct the second agent 416 to either the priming system 406 or the dispensing module 404. The diversion valve 410 may be similarly configured as the diversion valve 408

The dispensing module 404 includes a nozzle mechanism 428 configured to dispense cleaning agents inside a processing volume of the ICD module. In an example, the nozzle mechanism 428 may be a droplet nozzle mechanism configured to generate an atomized fluid jet formed by nitrogen and deionized water. The droplet nozzle mechanism may include two inlets for nitrogen and deionized water, respectively. The droplet nozzle mechanism include one dispensing nozzle configured to dispense the nitrogen and deionized water toward the substrate.

The priming system 406 includes a priming nozzle mechanism 430, a separation chamber 418, and a collection module 420. The priming nozzle mechanism 430 is configured to continue releasing the agents 414 and/or 416 during a time period when the dispensing mechanism 428 stops dispensing the agents 414 and/or 416. In an embodiment, the priming nozzle mechanism 430 includes two inlets 440, and 442 (shown in FIG. 4C) for the agents 414 and 416, respectively, and a releasing valve 446. The first inlet 440 is coupled with the diversion valve 408 that is capable of releasing the agent 414 inside a chamber 444 of the priming nozzle mechanism 430. The second inlet 442 is coupled with the diversion valve 410 that is capable of releasing the agent 416 inside the chamber 444. The agents 414, 416 are released to the separation chamber 418 by the releasing valve 446. The priming nozzle mechanism 430 is configured to simulate how the dispensing nozzle 428 dispenses the agents 414, 415.

Referring back to FIG. 4A, the separation chamber 418 is configured to separate the agents 414 and 416. In an example, one of the agents is a gas, such as nitrogen, and the other agent is a liquid, such as an aqueous solution. The separation chamber 418 includes a phase separator that is configured to separate a gas from a liquid. The phase separator may be a commercially available gas-liquid separator. The separation chamber 418 releases the separated agents 414 and 416 to the collection module 420, which is capable of storing agents 414 and 416 safely and separately.

The controller 412 is configured to control operations of the agent supply system 400. In an embodiment, the controller 412 is coupled with the agent supply module 420, the dispensing nozzle mechanism 428, the priming system 406, and the diversion valves 408 and 410. The controller 412 is configured to cause the diversion valves 408 and 410 to direct the agents 414 and 416 to the priming system 406 during a time period when the dispensing nozzle module stops dispensing the agent 414 or the agent 416. The controller 412 is also configured to cause the diversion valves 408 and 410 to redirect the agents 414 and 416 to the dispensing nozzle mechanism 428 during the end of the time period. In an embodiment, the time period includes any idling period of the dispensing nozzle mechanism 428 during the processing of a substrate. In another embodiment, the time period includes a pause period of the dispensing nozzle mechanism 428 during the processing of a substrate.

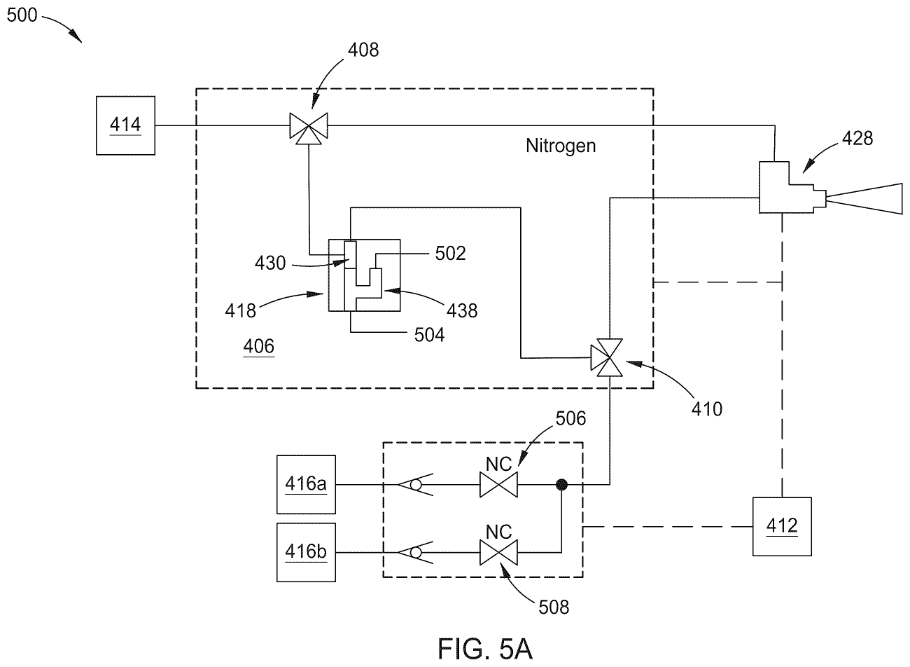

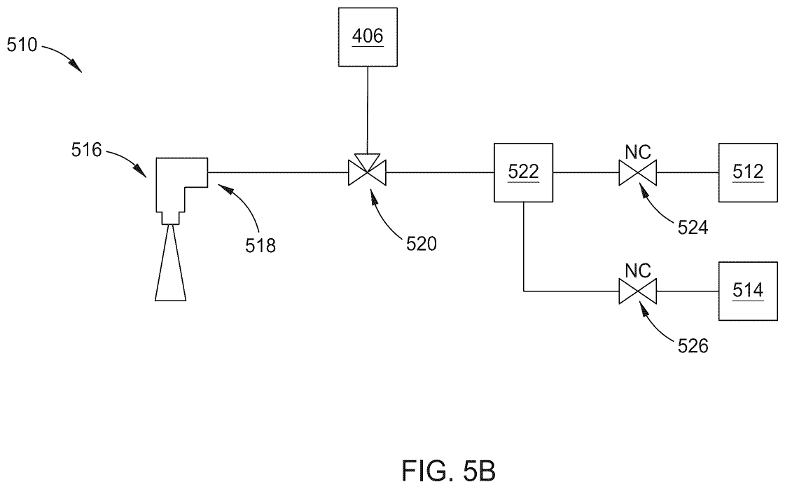

FIG. 5A illustrates an agent supply system 500 for a cleaning module, according to one or more embodiments. Whenever possible, identical parts in both FIGS. 4A and 5 are identified by the same reference numerals. Comparing with FIG. 4A, the agent supply system 500 includes two supply sources 416a and 416b for the agent 416. For example, the agent 416 may include deionized water and another chemical, such as ammonium hydroxide or any other chemicals. The agent source 416a may be provided to supply deionized water, and the agent source 416b may be provided to supply the other chemical. The agent source 416a is coupled with a normally closed valve 506 configured to control the flow of the agent source 416a. The agent source 416b is coupled with a normally closed valve 508 configured to control the flow of the agent source 416b. In an embodiment, the normally closed valve 508 may be shut off when the agent 416 is directed to the priming system 406, thus reducing waste and pollution caused by the agent 416b (a chemical). As shown in FIG. 5, the separation chamber 418 includes a liquid outlet 504 configured to release a liquid and a gas outlet 502 configured to release a gas.

FIG. 5B illustrates an agent supply system 510 for a cleaning module, according to one or more embodiments. In certain cleaning processes, a dispensing module 516 of a cleaning module may dispense a pre-mixed cleaning agent, such as a cleaning agent formed by pre-mixed nitrogen and isopropanol (IPA). The dispensing module 516, as shown in FIG. 5B, includes an inlet 518 that receives the pre-mixed cleaning agent. A diversion valve 520 controls whether to direct the pre-mixed cleaning agent to the dispensing module 516 or a priming system 406. The pre-mixed cleaning agent is supplied by a liquid agent source 512 and a gaseous agent source 514. A flow control valve 524 couples with the liquid agent source 512 and controls the flow of a liquid agent, such as IPA. A flow control valve 526 couples with the gaseous agent source 514 and controls the flow of a gaseous agent, such as nitrogen. A mixing valve 522 is configured to receive the liquid agent and the gaseous agent and then mix the two agents. The mixing valve 522 includes an expansion valve for the gaseous agent. The mixing valve 522 directs the mixed nitrogen and IPA to the diversion valve 520.

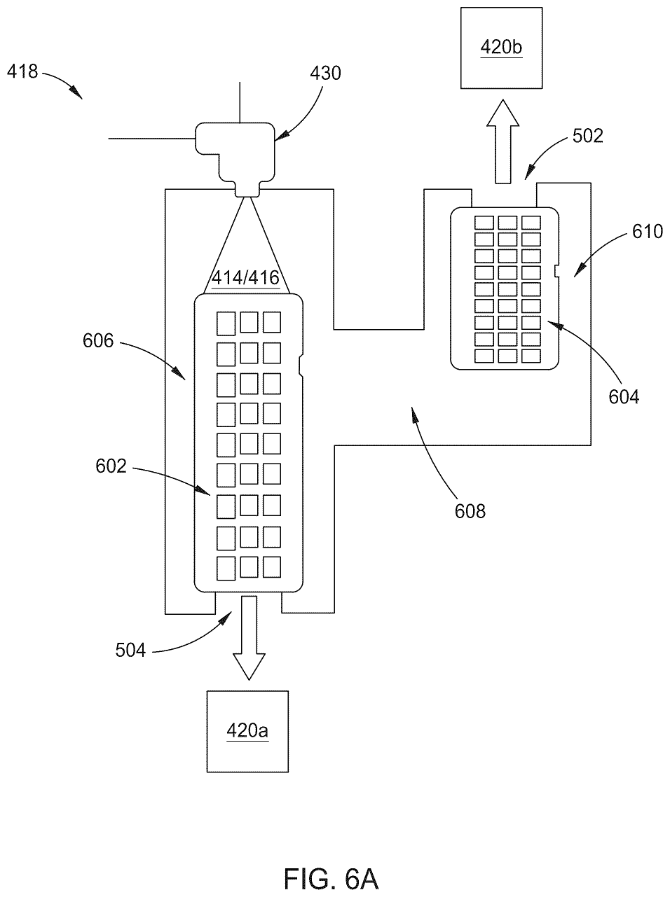

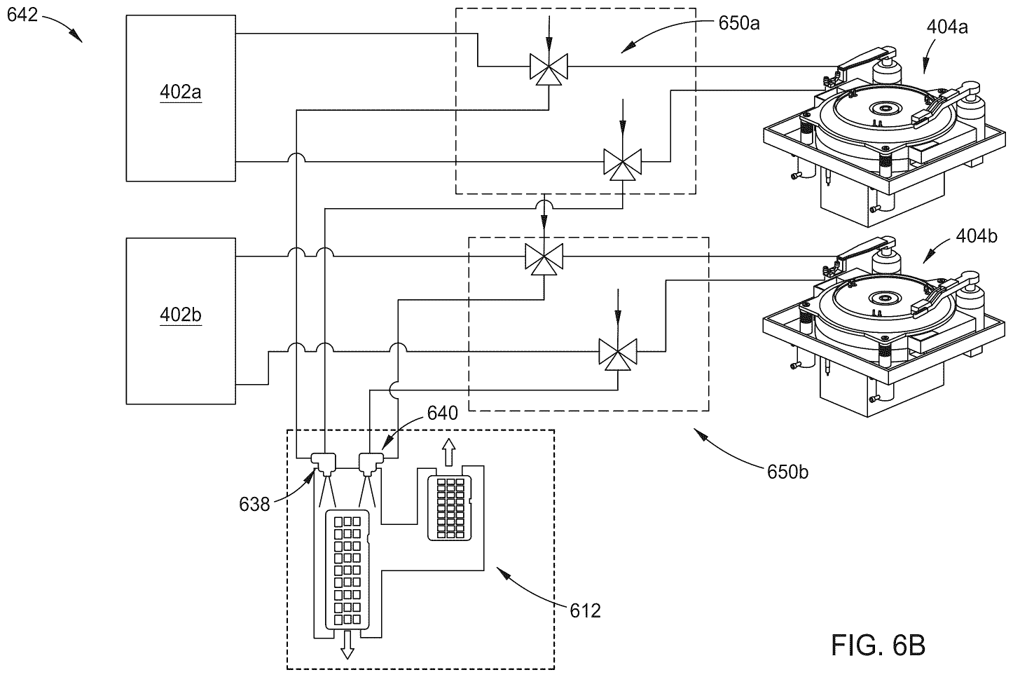

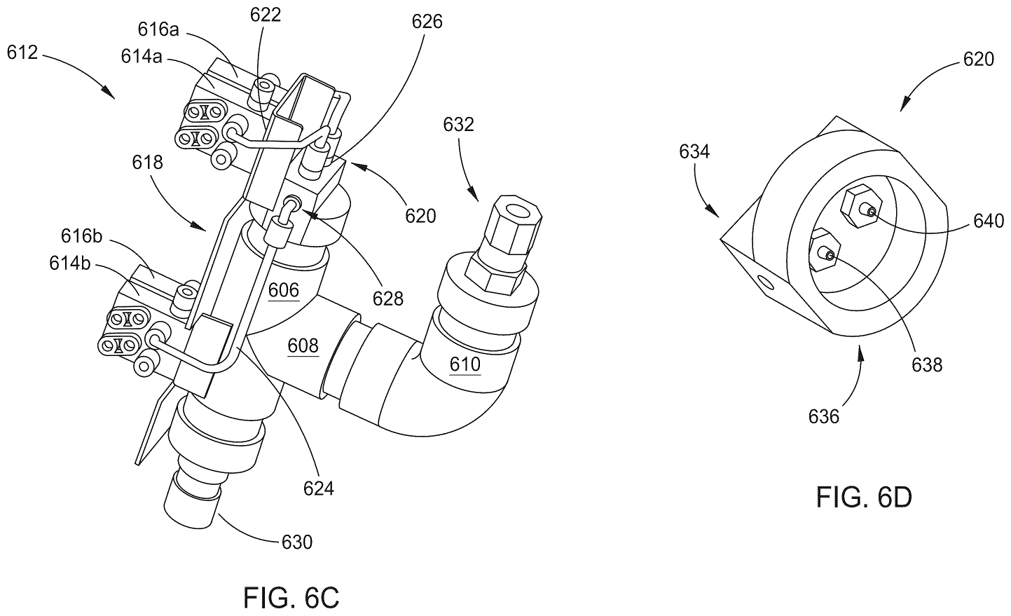

FIG. 6A illustrates a schematic cross-sectional view of a separation chamber 418, according to one or more embodiments. The separation chamber 418 is coupled with a liquid storage container 420a that can safely store a liquid released by the liquid outlet 504. The separation chamber 418 is also coupled with a gas storage container 420b that can safely store a gas released by the gas outlet 502. The priming nozzle mechanism 430 is configured to release the agents 414 and 416 inside the separation chamber 418.

In an embodiment, the separation chamber 418 includes a first phase separation chamber 606, a transfer chamber 608, and a second phase separation chamber 610. The first separation chamber 606 is arranged substantially vertically under the nozzles of the priming nozzle mechanism 430. The first separation chamber 606 can drastically reduce the kinetic energy of the fluid dispensed from the nozzles. A first phase separator 602, such as a fine mesh, is disposed inside the first phase separation chamber 606 and configured to separate the agents 414 and 416 into different phases. For example, the agent 414 may be a nitrogen gas, and the agent 416 may be an aqueous solution. The first phase separator 602 may be a gas-liquid separator configured to separate a liquid from a gas. When the agents 414 and 416 are dispensed into the separation chamber 418, the top surface of the first separation chamber 606 drastically reduces the kinetic energy of the fluid. Then, the separator 602, such as a fine mesh, disposed inside the first separation chamber 606 separates the liquid medium using the adhesive force. A fine mesh helps increase the surface area of contact, thereby enhancing the separation, and at the same time provides a free passage for gas to flow back to reach the exhaust port 420b. The separated liquid is drained by gravity to the drain port 420a. The separated liquid can be released to the liquid storage container 420a for chemical recycling or is drained through a drainage system. The separated gas can flow through the transfer chamber 608 into the second separation chamber 610. In an embodiment, the transfer chamber 608 is arranged horizontally. The second separation chamber 610 is also arranged vertically and has a second separator 604. The second separator 604 can further separate a liquid from a gas to provide dry gas to be exhausted through exhaust port 420b. For example, the second separator 604 & 602 may be a strainer made of stainless steel or PVC or PTFE or any non-reactive plastic. The separated gas can be pushed or vacuumed by exhaust negative pressure by pressure or vacuum inside the separation chamber to pass through the second separator 604 and then released into the gas storage container 420b for recycling or exhausted into an exhaust system.

FIG. 6B illustrates a schematic configuration of a priming system supporting two ICD modules, according to an embodiment. The priming system 642 includes one separation chamber 612 and two sets of diversion valves 650a and 650b. The first set of diversion valve 650a couples the agent source 402a to a first ICD module 404a. The second set of diversion valve 650b couples the agent source 403b to a second ICD module 404b. The separation chamber 612 includes two releasing valves 638 and 640. The releasing valve 638 is coupled with the first set of diversion valves 650a and is configured to release cleaning agents from the agent source 402a. The releasing valve 540 is coupled with the second sect of diversion valve 650b and is configured to release cleaning agents from the agent source 402b. With this configuration, a single separation chamber 612 can be used to prime two ICD modules.

FIG. 6C illustrates a schematic perspective view of a separation chamber 612, according to an embodiment of the present disclosure. The separation chamber 612 is configured to work with a plurality of ICD modules. In an example, the separation chamber 612 couples to two ICD modules (shown in FIG. 6B). Similar with the separation chamber 418, the separation chamber 612 includes a first phase separation chamber 606 having a liquid drain 630, a transfer chamber 608, and a second phase separation chamber 610 having a gas drain 632. To provide the priming function to two ICD modules, the separation chamber 612 includes a first set of diversion valves 614a and 614b and a second set of the diversion valve 616a and 616b. The two sets of diversion valves are attached to a bracket 618, which, in turn, is attached to the separation chamber 612.

The first set of the diversion valves 614a, 614b are coupled with a first ICD module (not shown), and the second set of the diversion valves 616, 616b are coupled with a second ICD module (now shown). The diversion valves 614a and 616a are configured for an agent of a liquid phase and may be collectively disposed at an upper part of the bracket 618. The diversion valves 614b and 616b are configured for an agent of a gaseous phase and may be disposed at a lower part of the bracket 618.

The separation chamber 612 includes a manifold 620 (also shown in FIG. 6D) configured to provide a coupling location between the diversion valves and the separation chamber 612. In an embodiment, the manifold 620 includes annular base 636 configured to couple with the first phase separation chamber 606. The manifold 620 may further includes a header 634 shaped like a cuboid and extending away from the annular base 636. Two releasing nozzles 638 and 640 are disposed on the header 634 and enclosed by the annular base 636, each coupling with a different ICD module. The diversion valves couple to the releasing nozzles via the header 634. For example, a liquid line 622 couples with the nozzle 638 at one end and with the liquid valve 614a at another end. A gaseous line 624 couples with the releasing 638 at one end and with the gaseous valve 614b at another end. The liquid line 622 may be secured to a top surface 626 of the manifold 620, while the gaseous line 624 may be secured to a side surface 628 of the manifold 620.

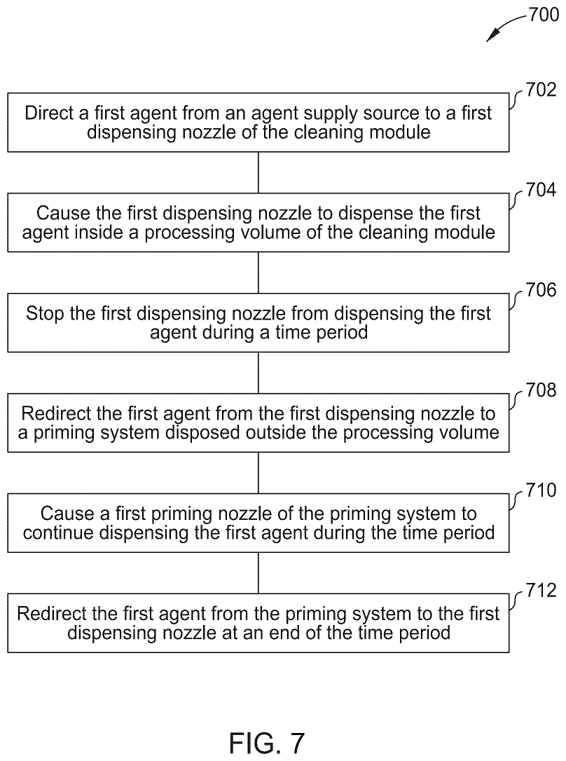

FIG. 7 illustrates a method for operating a cleaning module, according to one or more embodiments. The cleaning module includes a dispensing module configured to dispense agents inside a processing volume, in which a substrate is disposed. The cleaning module further includes a priming system disposed outside the processing volume. At operation 702, a controller causes a diversion valve to direct a first agent from an agent supply source to a dispensing nozzle of the cleaning module. At operation 704, the controller cause the dispensing nozzle to dispense the first agent dispensed inside the processing volume of the cleaning module. At operation 706, the controller causes the dispensing nozzle to stop dispensing the first agent during a time period. The time period may include any idle period of the first dispensing nozzle. For example, a sweeping arm including the dispensing nozzle may rest at the cup 225, during which the dispensing nozzle stops dispensing the first agent. At operation 708, the controller causes the diversion valve to redirect the first agent from the dispensing nozzle to the priming system disposed outside the processing volume. At operation 710, the controller causes a releasing nozzle of the priming system to continue releasing the first agent during the time period. At operation 712, the controller causes the diversion valve to redirect the first agent from the priming system to the dispensing nozzle at an end of the time period. For example, when the sweeping arm leaves the resting cup 225 and starts dispensing the first agent inside the processing volume, the first agent will be redirected back to the dispensing nozzle.

The cleaning module may further include a second agent. Thus, the method further includes operations for the second agent. For example, the controller may cause another diversion valve to direct a second agent to the dispensing nozzle of the dispensing module. The dispensing nozzle may dispense the second agent inside the processing volume simultaneously with the first agent. During the time period when the dispensing nozzle stops dispensing the first agent, the controller causes the dispensing nozzle to stop dispensing the second agent. Then, the controller causes the diversion valve to redirect the second agent from the dispensing nozzle to the priming system during the same time period. The controller further causes the releasing nozzle of the priming system to continue dispensing the second agent during the time period; and then causes the diversion valve to redirect the second agent from the priming system to the dispensing nozzle at the end of the time period.

While the foregoing is directed to embodiments of the present disclosure, other and further embodiments of the disclosure may be devised without departing from the basic scope thereof, and the scope thereof is determined by the claims that follow.

What is claimed is:

1. A priming system for a substrate cleaning module, comprising:
a first diversion valve configured to selectively direct a first flow of a first agent;
a priming nozzle mechanism coupled with the first diversion valve and comprising a releasing nozzle; and
a separation chamber coupled with the priming nozzle mechanism, wherein the priming nozzle mechanism is configured to release the first agent inside the separation chamber, the separation chamber configured to process the first agent.

2. The priming system of claim 1, wherein the first diversion valve comprises an input configured to receive the first flow of the first agent, a first output coupled with the priming nozzle mechanism, and a second output configured to couple with a dispensing nozzle of the substrate cleaning module.

3. The priming system of claim 2, wherein the releasing nozzle is configured to mimic dispensing the first agent by the dispensing nozzle.

4. The priming system of claim 2, wherein the first agent comprises a liquid and a chemical, and the input of the first diversion valve is coupled with a first valve configured to dispense the liquid and a second valve configured to dispense the chemical.

5. The priming system of claim 1, further comprising:
a second diversion valve configured to selectively direct a second flow of a second agent,
wherein the priming nozzle mechanism is coupled with the second diversion valve, and the releasing nozzle is configured to dispense the second agent in the separation chamber, the separation chamber configured to process the second agent.

6. The priming system of claim 5, wherein the second diversion valve comprises an input configured to receive the second flow of the second agent, a first output coupled with the priming nozzle mechanism, and a second output configured to couple with a dispensing nozzle of the substrate cleaning module.

7. The priming system of claim 1, wherein the first agent includes a gas or a liquid.

8. The priming system of claim 6, wherein the first agent comprises a nitrogen or an aqueous solution.

9. The priming system of claim 1, wherein the separation chamber comprises a phase separator configured to separate a gas from a liquid.

10. The priming system of claim 9, wherein the separation chamber further comprises a liquid outlet configured to release the liquid and a gas outlet configured to release the gas.

11. A cleaning module for cleaning a substrate, comprising:
a dispensing nozzle mechanism comprising a dispensing nozzle configured to dispense a first agent toward a substrate disposed inside a processing volume of the cleaning module;
a priming system disposed outside the processing volume and configured to release the first agent during a time period when the dispensing nozzle stops dispensing the first agent; and
a first diversion valve coupled with both the dispensing nozzle mechanism and the priming system and configured to selectively direct a first flow of the first agent,
wherein the priming system comprises a releasing nozzle coupled with the first diversion valve and a separation chamber configured to process the first agent, the releasing nozzle configured to release the first agent inside the separation chamber.

12. The cleaning module of claim 11, wherein the first diversion valve comprises an input configured to receive the first flow of the first agent, a first output coupled with the releasing nozzle, and a second output coupled with the dispensing nozzle.

13. The cleaning module of claim 12, wherein the releasing nozzle is configured to mimic dispensing the first agent by the dispensing nozzle.

14. The cleaning module of claim 11, further comprising:
a second diversion valve configured to selectively direct a second flow of a second agent,
wherein the releasing nozzle is coupled with the second diversion valve and configured to dispense the second agent inside the separation chamber.

15. The cleaning module of claim 14, wherein the second diversion valve comprises an input configured to receive the second flow of the second agent, a first output coupled with the releasing nozzle, and a second output coupled with the dispensing nozzle of the cleaning module.

16. The cleaning module of claim 11, wherein the first agent comprises a liquid and a chemical, and an input of the first diversion valve is coupled with a first valve configured to dispense the liquid and a second valve configured to dispense the chemical.

17. The cleaning module of claim 11, wherein the first agent comprises a nitrogen or an aqueous solution.

18. The cleaning module of claim 11, wherein the separation chamber comprises a phase separator configured to separate a gas from a liquid, a liquid outlet configured to release the liquid, and a gas outlet configured to release the gas.

19. A method for operating a substrate cleaning module, comprising:
directing a first agent from an agent supply source to a dispensing nozzle of a substrate cleaning module;
causing the dispensing nozzle to dispense the first agent inside a processing volume of the substrate cleaning module;
stopping the dispensing nozzle from dispensing the first agent during a time period;
redirecting the first agent from the dispensing nozzle to a priming system disposed outside the processing volume during the time period;
causing a releasing nozzle of the priming system to continue dispensing the first agent during the time period; and
redirecting the first agent from the priming system to the dispensing nozzle at an end of the time period.

20. The method of claim 19, comprising:
stopping the dispensing nozzle of the substrate cleaning module from dispensing a second agent inside the processing volume during the time period;
redirecting the second agent from the dispensing nozzle to the priming system during the time period;
causing the releasing nozzle of the priming system to continue dispensing the second agent during the time period; and
redirecting the second agent from the priming system to the dispensing nozzle at the end of the time period.
